(19) United States
(12) Patent Application Publication
(10) Pub. No.: US 2018/0297028 A1
(43) Pub. Date: Oct. 18, 2018

(54) SELF-POWERED MICROFLUIDIC CHIP WITH MICRO-PATTERNED REAGENTS

(71) Applicant: THE REGENTS OF THE UNIVERSITY OF CALIFORNIA, Oakland, CA (US)

(72) Inventors: Luke P. Lee, Orinda, CA (US); Erh-Chia Yeh, Alameda, CA (US)

(73) Assignee: THE REGENTS OF THE UNIVERSITY OF CALIFORNIA, Oakland, CA (US)

(21) Appl. No.: 15/946,615

(22) Filed: Apr. 5, 2018

Related U.S. Application Data
(63) Continuation of application No. PCT/US2016/056127, filed on Oct. 7, 2016.
(60) Provisional application No. 62/238,583, filed on Oct. 7, 2015.

(51) Int. Cl. B01L 3/00; B81B 1/00; B81C 1/00

(52) U.S. Cl. CPC B01L 3/502707; B01L 3/50273; B81B 1/006; B81C 1/00119; B01L 2300/0816; B81B 2203/0315; B01L 2300/0883; B01L 2400/0487; B01L 2400/049; B81B 2201/05; B81B 2203/0338; B01L 2300/0864

(57) ABSTRACT

A microfluidic apparatus and methods for fabrication with a fluidic layer and a pattern layer of spots of concentrated reagents that are disposed in wells of a fluidic layer when the two layers are bonded together. Reagents are stored on the chip prior to use. Because reagents are confined to specific wells, contamination of the channels and other microfluidic structures of the fluidic layer are avoided. The fluidic layer also has a system of vacuum channels and at least one vacuum void to store vacuum potential for controlled micro-fluidic pumping. The top and bottom surfaces of the bonded layers are sealed. The chip can be used for point of care diagnostic assays such as quantitative testing, digital nucleic acid amplification, and biochemical testing such as immunoassays and chemistry testing.

### CROSS-REFERENCE TO RELATED APPLICATIONS

This application is a 35 U.S.C. § 111(a) continuation of PCT international application number PCT/US2016/056127 filed on Oct. 7, 2016, incorporated herein by reference in its entirety, which claims priority to, and the benefit of, U.S. provisional patent application Ser. No. 62/238,583 filed on Oct. 7, 2015, incorporated herein by reference in its entirety. Priority is claimed to each of the foregoing applications.

The above-referenced PCT international application was published as PCT International Publication No. WO 2017/062864 on Apr. 13, 2017, which publication is incorporated herein by reference in its entirety.

### STATEMENT REGARDING FEDERALLY SPONSORED RESEARCH OR DEVELOPMENT

Not Applicable

### INCORPORATION-BY-REFERENCE OF COMPUTER PROGRAM APPENDIX

Not Applicable

### BACKGROUND

### 1. Technical Field

The present technology pertains generally to passive microfluidic diagnostic sensing systems, and more particularly to a Self-powered Integrated Microfluidic Point-of-care Low-cost Enabling (SIMPLE) chip, which is designed as a sample-to-answer solution for point-of-care quantitative nucleic acid testing.

### 2. Background Discussion

Ideal point-of-care medical diagnostic assays will be low in cost, portable, simple, rapid, and capable of quantitative nucleic acid detection. However, most diagnostic assays that are commercially available are qualitative, providing only positive/negative readouts, or require additional separate steps for DNA detection. The current standard for quantitative testing is real-time PCR, a process that is not well suited for low-cost field operations. This method generally involves laboratory equipment (e.g. thermal-cyclers and centrifuges) that require external power sources, several hours of assay time, multiple manual sample preparation steps, and trained technicians.

Therefore, the ideal point-of-care device would have simplified steps for direct sample-to-answer diagnostics on one portable chip. In order to achieve this, several obstacles need to be overcome including: (1) the pre-patterning of dried reagent thin films on chip for single-step sample-to-answer molecular diagnostics, (2) on-chip integration of sample preparation steps allowing minimal manual operation, and (3) autonomous fluidic pumping without any external equipment or power source for portability.

In order to accomplish the formation of pre-patterned reagent thin films, there is a need for a method that can pack sufficient amounts of reagents into highly defined dot-shaped footprints, so that multiplexed reactions can commence directly in microwells without cross contamination. Therefore, micro-patterning of reagents onto chips is a crucial technology for fabricating point-of-care devices that can be brought into the field.

Techniques such as inkjet printing or robotic contact pin-printers may create varying footprint sizes depending on substrate contact angle and sample viscosity. Other printing methods such as capillary printing, microfluidic networks, evaporation, and degas based printing usually create continuous line-shape patterns rather than dot-shape patterns.

Inkjet printers work by using piezoelectric shockwaves to expel liquids through a nozzle head. Although this method is rapid, there are several drawbacks with inkjet printing. First, the cost for specialized biological compatible inkjet printers can be very high and each service run can cost several thousands of dollars. The cost of maintenance is also high with these devices since the costly print heads can be easily damaged, clogged or contaminated with the printed medium.

Second, the final shape and printed footprint depends strongly on the hydrophilicity of the substrate and the viscosity of the ink medium. Due to uneven evaporation, coffee ring like concentration profiles are often observed at the outer boundaries of the printed pattern.

Third, to achieve spots with high concentrations, multiple print passes over the same area must be done. However, each pass needs to wait until the previous run is dry before performing the next run if a small footprint is desired. For example, a run with 40 passes (˜100 pl/pass) takes about 8 hours of machine time to complete with a biological inkjet type printer.

Finally, inkjet printing often requires special buffers or solvents to control the viscosity of the printed liquid, which may not be compatible with subsequent biological reactions such as nucleic acid amplification.

Another common technique is printing via robotic dispensers. As with inkjet printers, the robotic dispensers can be costly and not be part of a list of equipment that laboratories commonly possess. The main drawback of this method is the lack of resolution in order to print reagents into microfluidic structures. Smallest print volumes are typically in the range of hundreds or more nanoliters.

One important aspect of patterning is the ability to pattern reagents inside of microwells with a small footprint in order to isolate the reagents in the well. A small footprint will avoid bonding problems and also avoid reagent contamination in undesired areas. However, other methods such as capillary printing, microfluidic networks, evaporation, or degas based printing all create continuous-shaped patterns defined by the fluidic channels, which make it difficult or impossible to pattern inside the confinement of microwells.

There remains a need for a simple, low cost patterning technique that can pattern unconnected, concentrated, dot-shaped reagents that can be aligned into microfluidic structures such as microwells.

### BRIEF SUMMARY

The technology described herein provides an apparatus and methods for producing a point-of-care diagnostic microfluidic chip that is portable, low cost and capable of quantitative nucleic acid detection. Generally, the microfluidic chip platform is designed to function in low resource settings such as in rural villages in third world countries where there may be a lack of infrastructure, centralized labs, electricity, medical personnel, and funds for costly equipment. Potential applications of this chip include monitoring HIV viral load and the rapid detection of MRSA infection. Furthermore, it is possible to pattern different primers into the wells and perform hundreds of multiplexed detection for pathogens such as Ebola, Dengue, and Malaria on the same chip. Alternatively, this device can be adopted in hospital intensive care units for rapid multiplexed nucleic acid screening.

The preferred chip design has a closed microfluidic system and an associated vacuum system. The microfluidic system can be designed with microstructures, such microwells and microchannels that can be used to perform specific functions. The microstructures can also be designed and configured with dimensions that will perform separating functions.

The preferred chip structure is preferably composed of two layers of air permeable silicone material such as (PDMS). The top piece is a blank PDMS layer that has been patterned with one or more reagents on the bottom surface that is ultimately bonded to the bottom fluidic layer. The bottom fluidic layer consists of the selected design of fluidic components along with an optional large waste reservoir and vacuum battery voids that are punched into the bottom layer. These two layers are bonded together, typically by exposing them to UV light. Transparent pressure sensitive adhesive layers are added on the top and bottom of the two bonded layers to prevent excess air diffusion from the top and bottom surfaces of the layers. Users simply drop a sample into the inlet and the chip performs automatic sample preparation and analysis.

The top layer is pre-patterned with one or more types of reagents that are placed in selected microstructures such as microwells when the two layers are bonded. The pattern of reagents is preferably applied to the underside of the top layer with a four step process. In the first step, the bottom surface of the top layer is prepared to be hydrophilic and a patterned template that has hydrophobic surfaces is applied to the prepared surface of the top layer. The stencil can be made by microfluidic processes such as soft lithography or molding processes. The surface energy difference can be created by plasma treatment, UV ozone treatment, coatings, or heat treatment on the substrate or the stencil.

Reagents are introduced to the template and confined to cavities in the template. The reagents can be initiators such as MgOAc, DNA, RNA, enzymes or proteins or other molecules used for biochemical reactions or for isothermal nucleic acid amplification reactions etc. Digital micro-patterning of reagents allows for the placement of reagent directly in the microwells and independent reactions that are confined to the wells.

The cavities preferably have an asymmetric apex structure that allows the reagents to concentrate and create isolated spots of reagents with small footprints. The reagents are preferably confined into discrete spots by degas pumping using the patterning stencil. The patterned reagents adhere to the surface of top layer after top-patterning stencil is peeled off due to the surface energy difference between the substrate and stencil. Multiple patterns of different reagents can be applied to the top layer before bonding. The pattern specifically positions reagents into specific wells or other microfluidic structures of the fluidic layer.

The preferred embodiment of the chip has an integrated vacuum battery within the chip for autonomous microfluidic pumping without the need for external pumps. The pumping scheme may use degas pumping, or vacuum battery pumping, or proximal degas system to store and gradually release vacuum to drive fluid flow in a fully portable manner.

The preferred pumping scheme employs a vacuum battery system, which pre-stores vacuum potential in a void vacuum battery chamber, and discharges the vacuum over gas permeable lung-like structures to drive fluid flow more precisely. The degas driven fluid flow in this embodiment can operate without an oil phase for compartmentalization for digital nucleic acid, protein, antibody, detection etc. An air plug that follows after the receding liquid meniscus can automatically compartmentalize the sample in the wells.

The chip design can be tailored to perform digital nucleic acid amplifications and isothermal amplifications such as Recombinase Polymerase Amplifications as well as nucleic acid testing and other biochemical testing such as immunoassays and chemistry testing. The apparatus can also perform particle separations according to size and automatically separate blood cells from a fluidic flow in one embodiment.

One embodiment of the chip provides an alternative to real-time PCR for on-site rapid quantitative nucleic acid testing while maintaining the advantages of lateral flow assays in terms of affordability, simplicity, and portability. Another embodiment of the microfluidic chip is capable of on-site quantitative nucleic acid detection directly from blood without separate sample preparation steps. This chip has pre-patterned amplification initiator (MgOAc) within microwells of the fluidic system of the chip in order to achieve a sample-to-answer chip. This chip has a single-step sample preparation module where plasma is separated autonomously into 224 microwells (100 nl per well) without hemolysis.

The apparatus has several functionalities integrated into the chip including reagent microfluidic-patterning, on-chip sample preparation and separations, and equipment-free micro-pumping that allows quantitative digital nucleic acid detection using isothermal digital amplification (RPA), particle separations, and other desired sensing schemes. Isothermal amplification does not require thermal cycling equipment because all of the enzymatic processes are performed at a constant temperature. Digital amplification does not require real-time imaging and is also more robust than PCR, because end-point detection is less affected by environmental variations in temperature, kinetics, time, and imaging. Digital amplification works by compartmentalizing one sample into many individual miniature reactions. One can determine the original template concentration by counting the number of endpoint fluorescing compartments due to amplification.

The fluidic chips can also be heated to suitable elevated temperatures using heat sources, such as and not limited to heat packs, phase-change materials, exothermic chemistry reactions, water baths, ovens, and incubators.

According to one aspect of the technology, a microfluidic chip is provided with an integrated design with reagent microfluidic-patterning, on-chip sample preparation, and equipment-free micro-pumping.

Another aspect of the technology is to provide a microfluidic chip that is ideal for optical quantification, since it is made with highly transparent material (silicone), and there is no fibrous material interfering with the optical readout in contrast to lateral flow assays.

Another aspect of the technology is to provide a microfluidic chip that has controllable autonomous pumping with flow rate tunable by changing battery size and channel exchange surface area.

Yet another aspect of the technology is to provide a method for placing concentrated reactants into microfluidic structures using asymmetric apex reagent thin films that creates isolated spots and smaller footprints.

Another aspect of the technology is to provide an apparatus and method for on chip quantitative digital nucleic acid detection directly from human blood with dead-end microwell compartmentalization and automatic plasma and blood cell separations.

Further aspects of the technology described herein will be brought out in the following portions of the specification, wherein the detailed description is for the purpose of fully disclosing preferred embodiments of the technology without placing limitations thereon.

### BRIEF DESCRIPTION OF THE SEVERAL VIEWS OF THE DRAWINGS

The technology described herein will be more fully understood by reference to the following drawings which are for illustrative purposes only:

FIG. 1 is an exploded perspective view of a diagnostic sensing system with a microfluidic system with dead-end microwells containing micropatterned reagents and a vacuum battery pumping mechanism in accordance with one embodiment of the present technology.

FIG. 2A is a schematic cross-sectional view of a stencil with patterning channels with hydrophobic surfaces that has been applied to a blank layer to be patterned that has hydrophilic surfaces and evacuated as indicated by the arrows.

FIG. 2B is a schematic cross-sectional view of a stencil with patterning channels coupled to the blank layer and degas pumping of reagents.

FIG. 2C is a schematic top view of linear flow channels and cavities being loaded with reagent by degas pumping through the stencil channels. Degas pumping works by slowly sucking liquid when trapped air diffuses into pre-vacuumed air permeable silicone (PDMS) material.

FIG. 2D is a schematic top view of linear flow channels and cavities after loading. The arrows show the direction of flow.

FIG. 2E is a schematic top view of linear flow channels and cavities after a trailing air-gap removes reagents from flow channels and digitizes the reagents into discrete patterns. Digitization occurs when an air interface trailing after liquid loading separates patterns into discrete islands. Both stencils with patterning channels and bottom blanks may be made from PDMS.

FIG. 2F is a schematic cross-sectional view of a stencil with patterning channels coupled to the blank layer and cavities loaded with fluid reagents.

FIG. 2G is a detail cross-sectional view of a loaded cavity that is concentrated by drying/evaporating/absorbing the solvent. Reagents concentrate toward the cavity tip asymmetrically via capillary tension as indicated by the dashed arrow.

FIG. 2H is a schematic top view of a stencil with patterning channels and cavities showing asymmetric apex concentration of reagents.

FIG. 2I is a schematic cross-sectional view of the removal of the stencil from the patterned layer.

FIG. 2J is a schematic top view of the pattern of concentrated reagents on the patterned layer.

FIG. 2K is a schematic side view of the patterned layer that is flipped, aligned, and bonded on top of the layer containing microfluidic structures where the reagents are positioned in the microwells.

FIG. 2L is a schematic top view of the bonded top layer and bottom layer with the reagents specifically positioned in the microwells.

FIG. 3A is a schematic top perspective view of a microfluidic chip with patterned reagents, microfluidic system and vacuum battery pumping mechanism according to one embodiment of the technology.

FIG. 3B is a schematic longitudinal cross-sectional view of the vacuum battery of the chip of FIG. 3A. Black dashed arrows depict air diffusion across the permeable silicone into the vacuum battery drawing plasma into the microwells.

FIG. 3C is a schematic longitudinal cross-sectional view of a microwell portion of the microfluidic of the chip of FIG. 3A showing autonomous sample compartmentalization. A microcliff structure with a vertical side-wall and abrupt reduction in channel height facilitates plasma separation into the microwells. The microcliff skims plasma near the top of the microchannel into wells while blood cells sediments in the main channel. Plasma is drawn into the microwells when remaining air diffuses across the air permeable PDMS wall into the auxiliary battery as shown by dashed arrows.

### DETAILED DESCRIPTION

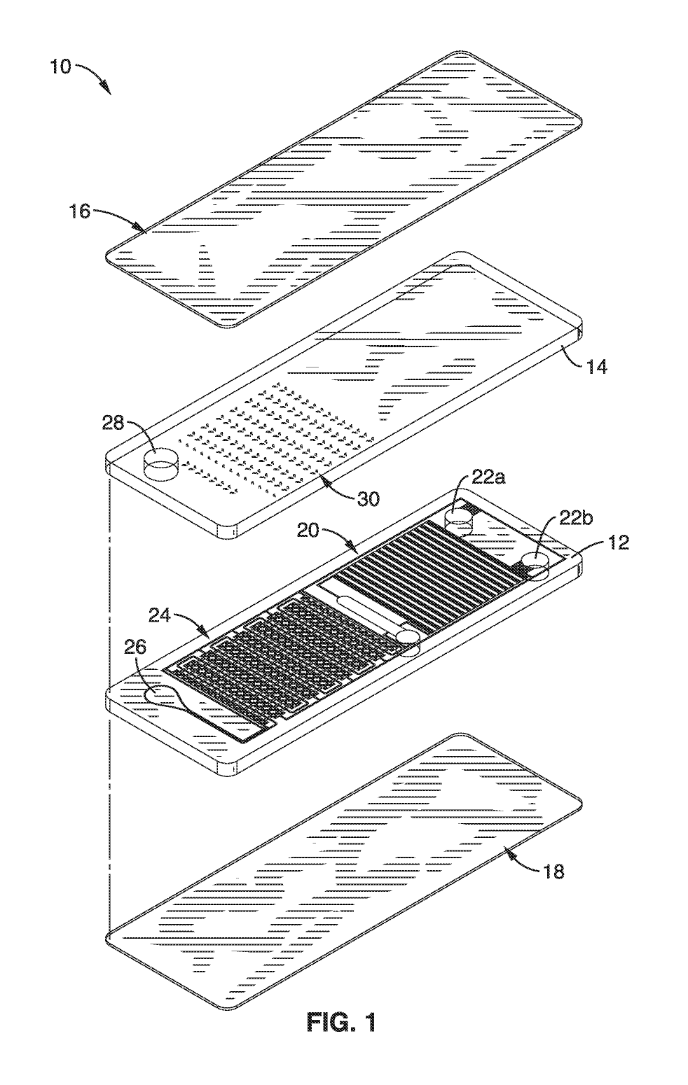

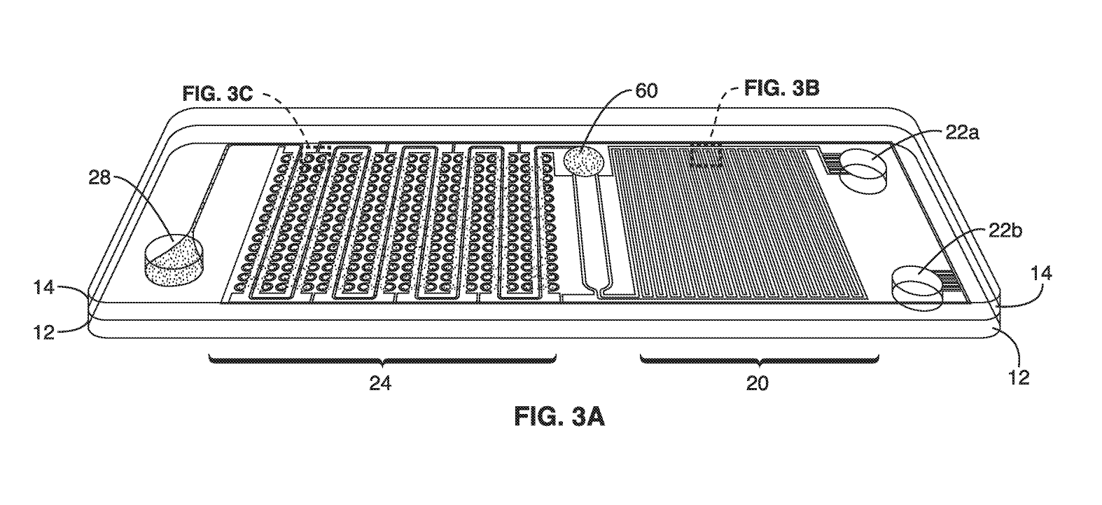

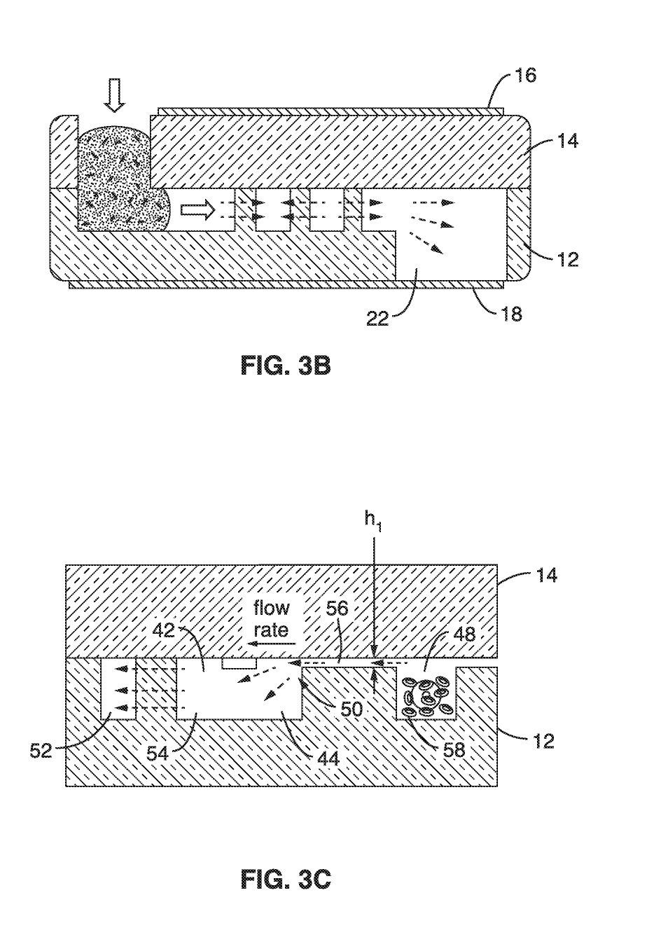

Referring more specifically to the drawings, for illustrative purposes, embodiment of a microfluidic chip structure and methods of fabrication are generally shown. Several embodiments of the technology are described generally in FIG. 1 through FIG. 3C to illustrate the systems and methods for fabricating and using a chip with concentrated micropatterned reagents disposed within microwells. It will be appreciated that the methods may vary as to the specific steps and sequence and the devices may vary as to structural details without departing from the basic concepts as disclosed herein. The method steps are merely exemplary of the order that these steps may occur. The steps may occur in any order that is desired, such that it still performs the goals of the claimed technology. The apparatus and methods are illustrated in a multi-welled microfluidic chip 10 as shown in the expanded view of FIG. 1 and FIG. 3A. The chip in this illustration has a simple construction with two layers of polydimethylsiloxane (PDMS) The device has a small footprint similar to a glass slide (25×75×6 mm), making it possible to be stored indefinitely and transported easily in airtight aluminum vacuum-sealed pouches.

Fabrication of the chip is straightforward and adaptable for scalable production and a simple two layer mold for injection molding/hot embossing with a thermal elastomer gas permeable material, such as PDMS.

The microfluidic chip 10 preferably has a top patterned reagent layer 14 and a bottom fluidic layer 12. The microfluidic layer 12 and the top pattern layer 14 are bonded together by exposing UV light to the PDMS. A transparent pressure sensitive adhesive sealing layer 16 is applied to the top patterned layer 14 and a bottom sealing layer 18 is added to bottom fluidic layer 12 to prevent excess air diffusion from the top and bottom surfaces of the two gas permeable (PDMS) layers.

The top pattern layer 14 is a blank PDMS layer that has been patterned with reagents 30 such as amplification initiator (MgOAc) on the bottom-bonding surface. The bottom fluidic layer 12 comprises fluidic components, a large waste reservoir and vacuum battery voids and channel networks. The reagents are preferably patterned to be within the wells of the bottom layer 12 when the two layers are joined.

The microfluidic chip 10 incorporates a vacuum battery system 20 that includes a main vacuum battery 22a and an auxiliary vacuum battery 22b that are each connected to networks of vacuum channels. Vacuum is pre-stored in the large “battery” voids. The vacuum battery system 20 uses vacuum battery voids to pre-store vacuum potential and gradually discharges the vacuum via air diffusion through the network of vacuum channels from inter-digitating fluid channels 24 or primary fluid channels to drive the flow of fluid through fluid lines and fluid channels and wells.

The vacuum battery 20 system components are connected to each other, but are not physically connected to or in fluid communication with the fluid lines, fluid channels or wells. It is important to note that the vacuum battery system 20 is not connected to fluid lines or channels of the fluidic system 24 since the vacuum would be instantly lost once the device is taken out of a vacuum environment if the fluidic system 24 and the vacuum system 20 were connected. Instead, the gas diffusion is controlled across walls of air permeable silicone material by design and the thickness and surface area of the walls regulate the flow properties.

The vacuum battery system 20 frees the chip 10 from the need of external pumps or power sources for pumping in this embodiment. Fluid is pumped by slowly releasing the pre-stored vacuum potential via air diffusion through diffusion structures.

In a preferred embodiment illustrated in FIG. 1, two vacuum battery components may be included on the bottom layer 12 of chip 10 to serve different purposes. The main vacuum battery 22a connects to the network of vacuum channels, and draws air in from the fluid channels via diffusion across the walls separating the fluid channels from the network of vacuum channels. It pumps the main fluid flow that goes from the inlet 26 through fluid lines of the fluidic system 24 into the optical window or waste reservoir 60.

An auxiliary well-loading vacuum battery 22b is connected to auxiliary vacuum lines or air channels adjacent to and between dead-end wells of the fluidic system 24. As in the main battery system 22a, the auxiliary well-loading vacuum battery 22b is not physically connected to the fluid channels, and instead only draws air in via diffusion across the thin PDMS walls separating auxiliary vacuum channels from wells, and assists in making the loading speed of the dead-end well's faster. It is also appreciated that the main 22a or auxiliary well-loading battery 22b is optional since conventional degas pumping can still cause the wells to be loaded, albeit at a slower speed.

The bottom fluidic layer 12 of the chip 10 includes a sample inlet 26 that receives the sample through an inlet port 28 in the top pattern layer 14. Once the sample has been loaded onto the chip 10, it flows through the fluidic system channels that are lined by wells in this embodiment.

For example, the user can introduce the sample onto the chip and sample flow starts automatically by using degas driven flow. Degas driven flow can be particularly useful at locations where acquiring electricity is not feasible. Degas driven flow operates by utilizing the inherently high porosity and air solubility of gas permeable materials such as PDMS by removing air molecules from the material (PDMS) changing pressures and initiating flow.

The vacuum battery system provides a more reliable flow, faster flow, and longer operation times compared to conventional bulk degas pumping. The use of the vacuum network enables a slower flow rate decay than observed with conventional degas pumping and easy flow tuning. Flow rate can also be easily tuned by changing the number of interdigitating pairs of vacuum and fluid line, which changes the air diffusion surface area. Flow rates decay slower with the vacuum battery system 20 when there are more channel pairs. In addition, it is possible to calibrate the microwell filling speed by varying vacuum strength. It was observed that there is an inverse relationship between compartmentalization time and vacuum battery volume. The vacuum battery system has been observed to always be faster and more consistent than conventional degas pumping.

Many different patterns 30 of reagents and types of reagents can be concentrated and formed on the bottom surface of top layer 14. One important aspect of patterning is the ability to pattern reagents inside of microwells. The small footprint avoids bonding problems and also avoids reagent contamination in undesired areas. In this illustration, the confinement of the reagents in the microwells is desired to avoid uncontrolled and unwanted nucleic acid amplification that may occur and create false positive signals.

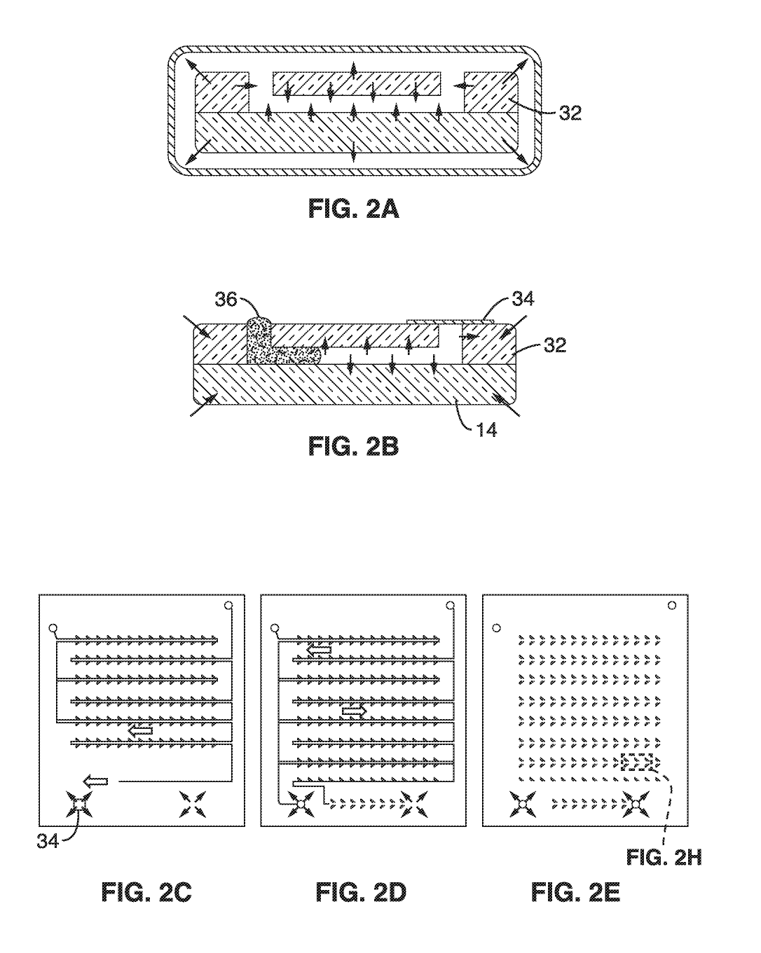

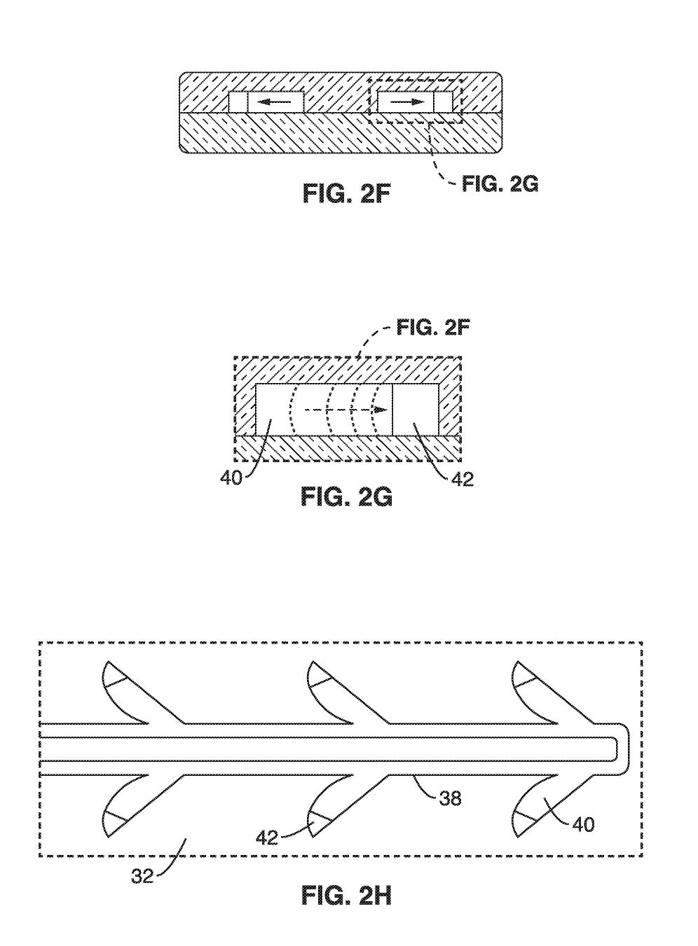

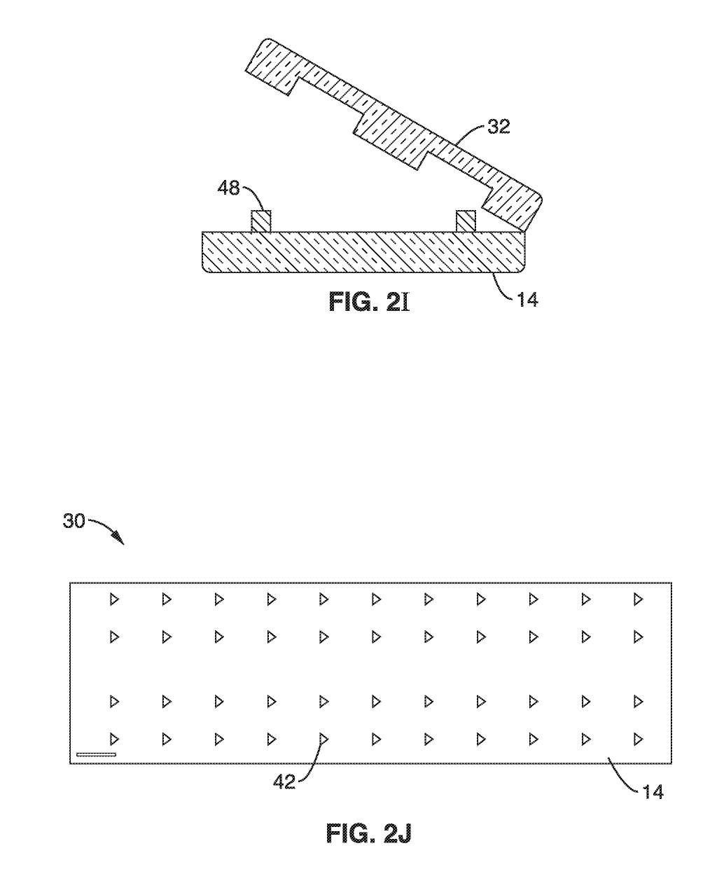

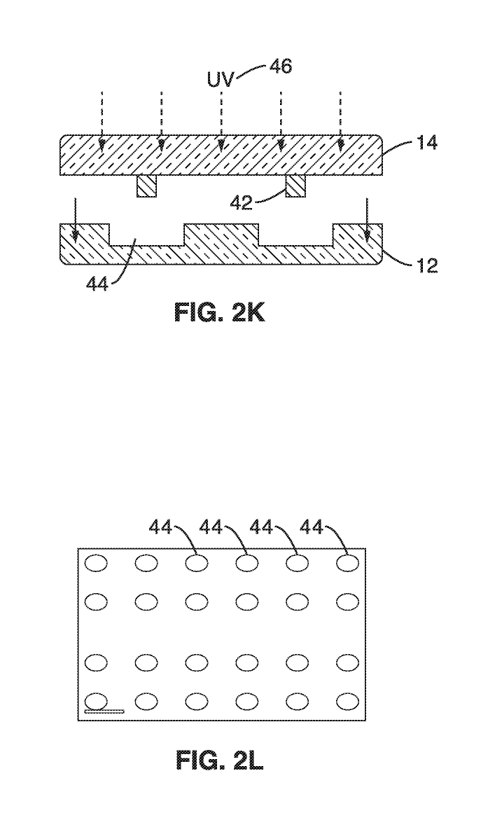

Turning now to FIG. 2A through FIG. 2L, a method for pre-patterning reagents on a substrate such as the top pattern layer 14 is set forth. This method enables production of dot-shaped micro-patterns of highly concentrated reagents into small footprints using asymmetric apex concentration. FIG. 2A to FIG. 2L shows cross sections of the top layer 14 to be patterned and ultimately being positioned and joined with the bottom fluidic layer 12.

A selected pattern of concentrated reagents can be created on the surface of the patterned layer 14 by applying a patterning stencil 32 on the surface of a blank layer 14. The patterning stencil 32 has a pattern of channels and side cavities that can accumulate reagents. A top view of a pattern with a branch and leaf design is shown in FIG. 2H. The surfaces of the blank layer 14 are preferably thermally aged and exposed to oxygen plasma to make the surfaces hydrophilic immediately before applying the stencil and loading in reagents. Since the surface of the pre-patterned stencil (PDMS) 32 is hydrophobic, the reagents will preferentially adhere to the hydrophilic blank surfaces. Accordingly, the reagents are preferentially patterned onto one surface by the surface energy differences between the substrate and stencil.

The blank layer 14 and attached stencil 32 are evacuated to remove air within the pattern of channels and cavities of the stencil 32. A tape seal 34 is placed over any outlets in the stencil to enclose the channels as shown in FIG. 2B.

Fluid reagents 36 are drawn into the evacuated microfluidic channels of the stencil and blank combination of air permeable PDMS materials using degas pumping as shown in FIG. 2B through FIG. 2E. The reagents are loaded by introducing a flow of reagents through the channels of the stencil as seen in FIG. 2C until the system is filled as shown in FIG. 2D. Degas pumping works by slowly drawing liquid when trapped air diffuses into pre-vacuumed air permeable silicone (PDMS) material.

The reagents 36 are separated into discrete locations when liquid loading finishes and the trailing air gap physically separates the reagents 36 into each cavity in the pattern. This step usually takes less than ˜15 minutes after loading. The sequestered reagent loaded cavities are illustrated in FIG. 2E.

The second step is concentrating the reagents asymmetrically into smaller footprints by drying as illustrated in FIG. 2F, FIG. 2G and FIG. 2H. In this particular design, the reagents 36 flow through flow channels 38 of stencil 32 and are distributed into the selected pattern of cavities 40 and optionally isolated with the air gap.

In the embodiment of the asymmetric apex design of the cavities shown in FIG. 2H, the cavity 40 has a linear side wall and an arcuate side wall that join at the apex. In the second step, the reagents 36 are concentrated towards the apex structure of cavity 40 asymmetrically due to capillary tension while air-drying, which creates isolated dot-arrays 42 of thin film reagent patterns. Otherwise, continuous lines of thin film reagents can interfere with the bioassay and cause bonding problems when integrated with the microfluidic layers. The dried patterns can have a footprint smaller than 200 μm in length. Drying decreases the footprint by a factor of 2. Decreasing foot is shown by dashed arrows in the detail of FIG. 2G. For visualization of the dried reagents 42, fluorescein or a food dye or similar material may be added. Drying under house vacuum further decreases the time needed to dry to a few hours.

The third step is peeling off the patterning layer 32. As shown schematically in FIG. 2I, the patterning stencil layer 32 is separated and removed from the patterned layer 14 with the dried reagents 42 forming the designated pattern 30 of reagents on the surface shown in FIG. 2J.

The dried reagents 42 adhere to the blank layer 14 after top-patterning stencil is peeled off. Since the surfaces of the channels and cavities of the top patterning stencil 32 remain hydrophobic, the reagents 42 preferentially stick to the hydrophilic surfaces of the bottom blank layer 14. The micro-patterned reagents 42 have a very uniform shape and area and no residue of reagents will be present in unwanted regions on the surface of the patterned layer 14.

The final step of assembling the reagent patterned layer 14 to place the reagents 42 within the microwells 44 of the fluidic layer 12 as shown in FIG. 2K and FIG. 2L. The patterned surface of the patterned layer 14 is aligned and bonded to the fluidic layer 12, typically with ultraviolet (UV) bonding 46. The reduced footprint of the reagents 42 prevents the patterns from overlapping with the bonding areas for a good seal and leaks can be avoided. It also helps reduce cross contamination risks.

After the chips are prepared they can be evacuated and sealed in an aluminum pouch with a vacuum sealer in one embodiment. The vacuum sealed pouches can be stored indefinitely and transported easily to remote areas. The user simply rips the seal open and loads samples in the intake. With the vacuum battery system, there is a long operation window of ˜2.5 hours for the user to load the chip.

It can be seen that the design of the vacuum system 20 and the fluidic systems 24 can be tailored to perform specific separations or functions. This is facilitated by the ability to place specific reagents into specific locations within the structures of the fluidic systems of the chip. Separations and isolations of sample components can also be an important capability of the fluidic chip.

The embodiment shown in FIG. 3A through FIG. 3C illustrate one possible configuration that is adapted for separations and assays. In FIG. 3A, the upper sealing layer 16 and lower sealing layer 18 have not been shown for clarity.

The chip shown in FIG. 3A and FIG. 3B incorporates a vacuum battery system 20 that uses reservoirs to store vacuum potential and gradually discharges vacuum via air diffusion through air or vacuum channels to drive the flow of fluid through fluid lines and fluid channels. There are two vacuum batteries on the chip shown in FIG. 3A. The illustrated chip incorporates a vacuum battery system 20 that includes a main vacuum battery 22a with a vacuum reservoir and interdigitating channels forming a vacuum “lung.” The main battery 22a assists with pumping the main fluid that flows from the inlet 28 into the waste reservoir 60. The auxiliary well-loading vacuum battery system 22b assists with microwell loading. The waste reservoir 60 retains the excess pumped liquid and prevents liquid from immediately flowing into the vacuum lung area, which would stop air diffusion prematurely. The vacuum battery 20 and vacuum lung components are connected to each other but are not physically connected to the fluid lines or fluid channels of fluidic system 24. In this configuration, it is possible to pump fluid without using any external equipment. Flow rate can be easily tuned by changing the battery size. It is also possible to increase flow rates with the addition of more paired channels and increasing the surface area of the vacuum channels of the structure.

The fluidic system 24 of the chip shown in FIG. 3A and FIG. 3C has rows of dead end microwells 44 connected to main fluidic channels 48 by a channel 56 generally perpendicular to the flow of channel 48. The microwell end of channel 56 forms a microcliff 50 entering the well 44. The dimensions the microcliff 50 and channel 56 can also be changed to include or exclude particles or components in the sample from fluids. The microwell 44 also has reagent 42 present within the well.

In the cross section of FIG. 3C, a configuration for plasma separations from blood cells 58 is illustrated. Air diffuses from the microwell 44 through the wall separating the well from the vacuum channel 52. This causes fluid from the fluidic channel 58 to be drawn through channel 56 and into the microwell 44. The flow rate into the wells can be varied by controlling the negative pressure applied to the auxiliary vacuum battery. Blood cells 58 tend to obscure DNA readout if they are not separated from plasma/fluids 54. When the gap size of h₁ of channel 56 increases, the separation efficiency in the top wells near the inlet have very poor blood separation efficiency because the blood cells 58 do not have sufficient time to sediment in the main flow channel 58 and may be sucked into the wells 44 along with the plasma 54. The depth of the main fluidic channel 48 can also be maximized. Smaller microcliff gaps and lower flow speeds can remove >95% of blood cells in the microwells and can retain higher DNA signal because of better blood cell separation.

The fluidic system 24 of the chip illustrated in FIG. 3A provides a large number of wells that are filled by dead-end loading. Dead-end loading is useful because it removes excess bubbles, which can cause clogging, or catastrophic ejection of liquid when heated. Dead-end wells 28 are also useful for multiplexed reactions, for example multiple diseases can be screened in different wells.

Likewise, dead-end wells 28 can be useful in digital PCR applications, where one PCR reaction is partitioned and compartmentalized into multiple smaller volumes of reactions, and each chamber reaction runs until saturation for a digital readout. Dead-end loading is especially useful for PCR reactions because it minimizes problems resulting from evaporation.

However, it is not possible to load dead-end wells with conventional capillary loading and conventional degas pumping is too slow. Dead-end loading is only possible because of the vacuum battery system 20 of the chip. The vacuum battery system provides a controlled flow, because more vacuum storage is possible with the battery void and air only needs to diffuse through thin PDMS walls in the vacuum channels 52, resulting in more consistent pressure gradients than found in conventional degas pumping, where air has to diffuse across large distances in the bulk PDMS.

Accordingly, this platform can be used to design a whole new generation of low-cost, portable, automated microfluidic point-of-care devices. With minimal manual operation, the portable chip can also perform digital quantitative nucleic acid detection directly from human whole blood samples in approximately 30 minutes via isothermal Recombinase Polymerase Amplification (RPA), for example.

The invention may be better understood with reference to the accompanying examples, which are intended for purposes of illustration only and should not be construed as in any sense limiting the scope of the present invention as defined in the claims appended hereto.

### Example 1

In order to demonstrate the apparatus and methods, a microfluidic chip platform was fabricated and tested. The chips were fabricated using a standard soft lithography process. Generally, the bottom 3 mm PDMS fluidic layers were made by casting PDMS on a silicon wafer that had protruding microfluidic channels created from photo-patterned (OAI Series 200 Aligner) SU-8 photoresist (Microchem). The main fluid and vacuum channels were 300 μm in height. The microcliff gaps were formed with heights of 40 μm, 120 μm, 170 μm, 240 μm and 300 μm for evaluation. A waste reservoir was created with a 5 mm puncher. The vacuum battery void was fabricated by simply punching the bottom 3 mm PDMS fluidic layer with through holes. Different diameters of punchers (Harris Uni-Core, Ted Pella) were used to fabricate the desired vacuum battery volumes. A separate top blank piece of 3 mm PDMS was bonded on the top side to seal the fluidic layer by oxygen plasma bonding using a reactive ion etching machine (PETS Reactive Ion Etcher, at 100 W, 120 mtorr O₂, 15 s). All chips were made the same size (25×75 mm), which is the same footprint as a standard microscope glass slide.

To increase the device assembly throughput, a master silicon mold was replicated by casting urethane plastic over the molded PDMS devices placed in square petri dishes. A thin layer of release agent was applied to the surface of the petri dishes to prevent urethane from sticking. The PDMS devices and urethane resin were degassed before casting, so no air bubbles would be trapped. The first hour of curing was done at 4° C. to lower viscosity and to slow curing of the urethane resin thus further avoiding air bubbles. Afterwards, the resin was left to cure at room temperature overnight and removed from the petri dishes. PDMS was poured into the hardened urethane molds to make devices.

For the RPA experiments, a blank PDMS layer was patterned with MgOAc and the microfluidic surfaces were passivated with an anti-biofouling surface treatment so non-specific adsorption of protein/DNA would be minimized. Finally, transparent PCR tape was taped on both the bottom and top surface of the chip to prevent excess gas diffusion and seal off the vacuum battery voids. New chips were used for each experiment.

The blank PDMS layer with the adhering MgOAc at 100° C. was thermally aged for at least three days, then the surfaces were exposed to oxygen plasma (PETS Reactive Ion Etcher, 100 W, 120 mTorr O₂, 50 s) to make the surfaces hydrophilic. The heat treatment prevented the hydrophobic recovery of the plasma treated PDMS surface. After plasma treatment, the blanks were immediately assembled with a patterning stencil (also made by soft lithography, with 30 μm thick microfluidic features) and vacuumed at 30 mTorr for 10 minutes. Then the outlets of the patterning chips were sealed with adhesive tape and 2 μl of magnesium acetate solution (MgOAc 1 M, Sigma Aldrich 63052) was pipetted to each of the inlets immediately. In some, fluorescein dye was added to allow the later acquisition of fluorescence pictures. After finishing autonomous loading by degas pumping (˜10 min), the tape was removed from the outlet and excess MgOAc was aspirated. The chip was left to air dry in atmosphere for 1 day before peeling. After drying, the patterning layer was peeled off in the direction from the base of the leaf patterns to the tips of the leaf patterns. The patterned MgOAc remained on the blank chip due to less hydrophobicity than the patterning stencil PDMS.

After the blank PDMS layers were patterned with MgOAc, the layers were bonded to the chips that contained the microfluidic wells and channels for the digital plasma separation design using UV light for 3 minutes. The chips were aligned manually under a stereoscope. The chips were then incubated immediately at 60° C. for at least 20 min after the UV bonding. A ˜0.5 kg weight was placed on the chips to increase bonding strength. For the reconstitution test, the final assembled chips were incubated at −95 kPa overnight and water was loaded into the chip to dissolve the MgOAc. The devices were sealed in aluminium vacuum packs by a vacuum sealer where long-term storage or transportation was necessary.

The vacuum battery and lung surface areas of the chip structure were evaluated. For these evaluations, 200 μl of diluted blue food dye were pre-loaded into PTFE tubes (Microbore PTFE Tubing, 0.03″ ID) that had a steel tubing connector (SC20/15, Instech Solomon) connecting to the chip. The tubing was connected to the inlet of the devices after taking the devices out of vacuum. The conventional degas (no-battery) devices had PDMS cured into all the vacuum lines to fill the vacuum battery structure. The conventional degas and with-battery devices had exactly identical fluidic channels, except that the conventional degas device had all of the vacuum lines and battery voids filled with cured PDMS (via degas pumping). The volume of food dye pumped was monitored by taking a time-lapse video and then quantifying using imaging software. Triplicates were performed for each data point. Battery volume was changed by punching holes with different diameters. The vacuum lung surface area was modified by creating new molds with different numbers of lung pairs. Flow rates within the apparatus were evaluated by using a 100 μl of diluted blue food dye, 1:25 diluted in water that was pipetted into the inlet of the apparatus at different time gap intervals.

### Example 2

Functional testing of the chip designs was conducted to demonstrate digital plasma separations, hemolysis and isothermal digital amplification. The digital plasma separation design (FIG. 3C) prepares the sample for digital amplification by simultaneously enabling (1) autonomous plasma separation and (2) autonomous sample compartmentalization. A microcliff structure (FIG. 3C) with a vertical side-wall and abrupt reduction in channel height facilitates plasma separation into the microwells. The microcliff skimmed plasma near the top of the microchannel into the wells while the blood cells sedimented in the main channel. Plasma was drawn into the microwells when the remaining air diffused across the air permeable PDMS wall into the auxiliary battery.

The flow field is described by the Navier-Stokes equation as the blood cells experience gravitational force and Stokes drag. Separation of the blood cells ensures that there is minimal optical obstruction of the fluorescence signal and minimal polymerase inhibition from hemoglobin in red blood cells. FIG. 3C shows the simultaneous plasma separation and sample compartmentalization (224 microwells, 100 nl well⁻¹) for digital amplification. No clogging was observed with this design.

To illustrate digital plasma separation, the main channel flow was kept at a rate of 5 μl min⁻¹ using a syringe pump. The flow rate into the wells was also controlled by tuning the vacuum strength with the auxiliary battery.

The DNA was dyed with green fluorescence (Toto-1 Iodide, Invitrogen), by mixing DNA (10¹³ copies μl⁻¹, MRSA) with 400× Toto-1 (diluted in 3.5×TBE) at a ratio of 1:50, and then incubating for 1 hour at 55° C.

Human whole blood (HMWBACD, Bioreclaimation) was dyed with fluorescence (Cellmask orange C10045, Invitrogen), by mixing 2× Cellmask dye (diluted in 3.5×TBE) into human whole blood (4:9 ratio), and incubated at 37° C. for 20 min. The dyed blood was centrifuged 5 times (1300 rcf, 5 mins); the supernatant was removed each time and replaced with fresh 3.5×TBE buffer.

Finally the stained DNA was added to the stained blood to make a final mixture that had 20% (vol/vol) blood. This mixture was loaded into the SIMPLE chip and the separation efficiency was quantified. Separation efficiency was calculated as 1-(blood intensity in well-background intensity)/(blood intensity in main channel-background intensity). Data was acquired with chips that had different microcliff gaps of 40, 120, 170, 240, 300 μm similar to that shown in FIG. 3C.

To demonstrate digital plasma separation control, the same blood sample was dropped directly into the chip. All chips were prepared with a 40 μm microcliff gap, 16 lung pair, 100 μl vacuum battery design and incubated at −95 kpa vacuum for 24 hrs before the test. The absorbance inside the microwells was measured with a spectrometer (USB 2000, Ocean Optics) mounted to a microscope (BX51, Olympus) at 50× zoom. The background was normalized to a chip loaded with only PBS.

Hemolysis testing with free blood cell removal was also illustrated. The microcliff design was shown to reduce blood cell entry into the microwells significantly. Blood separation fails if there is no microcliff structure present. When blood cells enter the wells, substantial obstruction of fluorescence signal from dyed DNA can occur. Separation efficiency was observed to surpass 95% when the microcliff gap (h1) or flow rate across cliff is reduced. In the without-cliff negative control, the concentration of blood cells in the microwells was slightly higher than the original sample, contributing to a negative efficiency. This is likely due to inertial effects. In contrast, the h1=40 μm microcliff gaps had the best and consistent separation efficiency across the chip spatially, and allowed 100% compartmentalization success.

No hemolysis was observed with the separations. Chips loaded with blood, ultrasound lysed blood, and centrifuged plasma were compared. For the ultrasound treated control, blood (20% human whole blood in PBS (vol/vol) was lysed with 120 W 40 Hz ultrasound (GB-2500B, Greenultrsonic) for 90 min. This was then loaded into the chip. For the centrifuge control, the same blood sample was centrifuged for 10 min at 1300 RCF and the plasma supernatant was extracted. The supernatant plasma was then loaded into another chip.

The quality of on-chip separated plasma was indistinguishable from centrifuged plasma when absorbance was measured in the microwells. Selective particle separation was also possible according to diameter. Particles larger than 1 μm separated while particles less than 100 nm were retained in the wells. Plasma separation was achieved within 12 min, with a total volume of ˜22 μl plasma.

To demonstrate the isothermal digital amplification functionality, DNA and RNA detection experiments were designed and the chips had magnesium acetate pre-patterned into the wells and the fluidic surface was treated with an anti-biofouling treatment. The DNA (MRSA) detection experiments were performed with the Recombinase Polymerase Amplification (RPA) EXO kit (Twistdx) and RNA (HIV-1) experiments were performed with an RPA RT EXO kit.

For reaction time experiments with HIV-RNA 10 μl of human whole blood (HMWBACD, Bioreclaimation) was mixed with a RPA mix (RPA RT-EXO enzyme pellet, 40 μl of primer/probe mix at 10 μM, 59 μl of rehydration buffer, 2 μl of 10% (wt/vol) BSA, 8 μl of RNAsin, and 2 μl of spiked HIV-1 RNA at 2*10⁵ copies μl⁻¹). Then 100 μl of blood/RPA mix was added into each chip and incubated at 40° C. while fluorescent time-lapse images were taken with a stereoscope.

For the DNA quantification experiments, 2.5 μl of human whole blood was mixed with a RPA mix (RPA EXO enzyme pellet, 1.6 μl of primer/probe mix at 100 μM, 59 μl of rehydration buffer, 2 μl of 10% (wt/vol) BSA, 35 μl of water, and 2.5 μl of spiked MRSA DNA at desired concentration). Then 100 μl of blood/RPA mix was added into each chip and incubated at 40° C. on instant heat packs for 1 hour, and then endpoint fluorescent images were taken with a stereoscope.

Quantitative detection of MRSA DNA (Methicillin-Resistant Staphylococcus Aureus) from 10-10⁵ copies μl⁻¹ was possible in water and also directly from spiked human whole blood.

Recombinase polymerase amplification was chosen because it is much more robust in plasma samples than PCR or Loop Mediated Isothermal Amplification (LAMP). RPA is also a fast amplification method, and operates at lower temperatures (e.g. works at 25° C. with ˜39° C. optimal).

A fluorophore-quencher molecular probe was used that only fluoresces when amplicons that have a matched sequence are present, therefore minimizing the possibility of false-positive signals. A reusable commercial sodium acetate instant heat pack can provide ˜40° C. heating for up to an hour for isothermal amplification.

Poisson statistics were used to determine digital amplification sensitivity range according to well size, we chose 100 nl for the well size and 224 wells because it allows a detection range that is physiologically relevant. It was possible to rapidly detect signals of HIV-1 RNA spiked in human blood (2*10⁵ copies μl⁻¹) within 18 min.

### Example 3

To demonstrate the methods for micro-patterning reagents, chip top sections were produced with a pattern of unconnected, concentrated, dot-shaped reagents that were configured to be aligned with micro-wells in the bottom section of the chip. One important aspect of patterning is the ability to pattern reagents to be disposed inside of microwells. Conventional low cost printing methods all create continuous-shaped patterns defined by the fluidic channels, which make it difficult or impossible to pattern inside the confinement of microwells. The small footprint avoids bonding problems and also avoids reagent contamination in undesired areas. In this illustration, it was necessary to confine the reagents in the microwells, otherwise, unwanted nucleic acid amplification may occur and create false positive signals.

In this example, the printing method, termed “digital micro-patterning,” is used to pattern magnesium acetate, an amplification initiator for isothermal nucleic acid amplification (recombinase polymerase amplification), individually into hundreds of microwells and achieve digital isothermal amplification within these wells.

Magnesium acetate, needed to be patterned into the wells because if it were to contaminate any of the main fluidic channels in the final assembled chip, isothermal amplification would commence prematurely and cause false positive signals. Magnesium acetate starts recombinase polymerase amplification reaction because the polymerase needs a certain concentration of magnesium ions to be active. For this reason, it was crucial to have a small footprint so that magnesium acetate do not contaminate outside of the microwells. Also a small footprint avoids bonding issues because reagents do not interfere with PDMS contact during bonding. Finally, a high density of reagents was desired, and this method was unique in the sense that it made it possible to pack reagents in a 3D block with a very clear and defined footprint. Contact printing cannot achieve this kind of 3D stacking, and inkjet printing's footprint starts to smear out when a high volume of liquid is printed.

One key advantage to this method is that it enables production of dot-shaped micro-patterns of highly concentrated reagents into small footprints. Asymmetric apex concentration is a unique feature that allows this concentration of selected reagents. Furthermore, common laboratory equipment may also be used and no specialized solvents are needed.

There are four main steps for digital micro-patterning reagents. In the first step, the reagents were loaded and separated into discrete islands (˜2 nl) automatically using a fluidic design that incorporated degas pumping. Fluid was drawn into the microfluidic channels when pre-vacuumed air permeable PDMS material gradually sucked out trapped air pockets. The reagents were separated when the liquid loading finished and the trailing air gap physically separated in each “leaf” pattern. This step usually takes less than ˜15 minutes after loading.

The second step concentrated the reagents asymmetrically into smaller footprints by drying. The dried patterns have a footprint smaller than 200 μm in length. The footprint decreased by a factor of 2 after drying. For visualization, fluorescein or food dye was added for imaging. These results show it was possible to reduce the footprint and solidify MgOAc by simply air-drying in atmosphere overnight. Drying under house vacuum further decreased the time needed to dry to a few hours.

The third step separates the patterning layer from the patterned blank. This step allows one to asymmetrically pattern all of the MgOAc patterns onto the blank PDMS layer by creating a difference in surface energy. The blank surface was pre-treated with heat at 100° C. for at least three days and then exposed to oxygen plasma immediately before performing the first step digitization. The plasma treatment made the blank PDMS surface hydrophilic and the heat treatment prevented the PDMS surface returning to a hydrophobic state. The oxygen plasma machine was optional and only needed to render hydrophobic substrates such as PDMS to a hydrophilic surface, if the substrate is inherently hydrophilic (e.g. glass), then plasma treatment is not required.

Since the top patterning PDMS remained hydrophobic, the MgOAc preferentially sticks to the hydrophilic bottom blank surface. In addition, it was found that peeling in the direction away from the sharp tips gives better yields. The micro-patterned MgOAc showed a very uniform shape and area under the microscope (average area was 2.3×10⁴ μm², and standard deviation was 0.1×3×10⁴ μm²). No residue of MgOAc was observed in unwanted regions.

The final step was the assembly of the upper MgOAc patterned layer with the lower microwell layer. UV bonding and manual alignment was used under a stereoscope for bonding. The reduced footprint of the MgOAc prevented the patterns overlapping with the bonding areas, thus leaks were avoided. The patterning channels were designed to not have any overlaps with the fluidic channels, therefore even if there were any residue outside of the desired patterning areas, it would not come into contact with the fluidic channels. After bonding, the reconstitution uniformity was tested by loading water into the patterned microwells using degas loading. The reconstituted fluorescence intensity distribution was more spread than after the concentrated MgOAc after the drying step, but still within tolerable ranges as subsequence RPA reactions were still viable. This may be caused from degradation of the fluorescein during the UV bonding step. As a proof of concept, the on-chip micro-patterns amplification initiator allowed the performance of isothermal digital nucleic acid amplification directly in the microwells.

Due to the low requirements of infrastructure, digital micro-patterning can be easily performed in any lab that has basic equipment. The patterning PDMS molds containing microfluidic patterns can be fabricated by facilities that have lithography capability and sent to the laboratories mentioned above for in-house PDMS replication molding. Thus, this technique is well suited for low-cost micro-patterning of highly concentrated reagents.

Another merit of this method is that unlike inkjet printers, that require addition of viscosity/evaporation modulation buffers, digital micro-patterning does not require any special solvents. That means there is less chance for interference with downstream assays (e.g. PCR or isothermal amplification). In this system, only water was used as the solvent. Nevertheless, the system is not limited to water and the system can use other types of solvents or materials.

From the description herein, it will be appreciated that that the present disclosure encompasses multiple embodiments which include, but are not limited to, the following:

1. A method for micropatterning materials on a substrate, the method comprising: (a) obtaining a substrate to be patterned; (b) forming a stencil with and inlet and a defined pattern of a plurality of fluidic channels and terminal cavities; (c) reversibly coupling the stencil with the substrate: (d) loading a fluid with a material to be patterned in the fluidic channels and cavities through the inlet; (e) clearing the channels of fluid; (f) removing the remaining liquid within the cavities to leave the material; and (g) separating the stencil from the substrate; (h) wherein the material is adhered to the substrate in a pattern defined by the cavities of the stencil.

2. The method of any preceding embodiment, further comprising: selecting a substrate that has a surface to be patterned that is hydrophilic; and forming the stencil with surfaces that are hydrophobic; wherein materials are preferentially patterned onto the surface of the substrate by surface energy differences between the substrate and stencil.

3. The method of any preceding embodiment, wherein the surface energy difference on the surfaces of the substrate or stencil is created by a process selected from the group of process consisting of a plasma treatment, a UV ozone treatment, an application of a coating, and a heat treatment.

4. The method of any preceding embodiment, wherein the stencil is made from a gas permeable material.

5. The method of any preceding embodiment, wherein microfluidic vacuum degas flow is used to load fluid in the defined patterns of channels and cavities.

6. The method of any preceding embodiment, wherein the cavities of the stencil further comprise: an asymmetric apex shape; wherein removing the remaining liquid within the cavities concentrates the material in the apex; and wherein removing the remaining liquid within the cavities reduces the dimensions of material.

7. The method of any preceding embodiment, wherein the cavities of the stencil have an arcuate side wall, a linear sidewall joined at an apex to for the asymmetric shape of the cavity.

8. The method of any preceding embodiment, the stencil further comprising: a second defined pattern of a plurality of fluidic channels and terminal cavities; and a second inlet coupled to the fluidic channels; wherein a second fluid with a second material can be loaded to the channels and cavities through the second inlet to produce a defined pattern of a second material.

9. The method of any preceding embodiment, wherein the cavities of the second pattern in the stencil further comprise: an asymmetric apex shape; wherein removing the remaining liquid within the cavities concentrates the material in the apex; and wherein removing the remaining liquid within the cavities reduces the dimensions of material.

10. A method for fabricating a microfluidic chip for analysis of a fluid sample, the method comprising: (a) patterning an inner surface of a pattern layer of a gas permeable material with one or more reagents; (b) forming a fluidic layer of a gas permeable material configured to separate a fluid sample into wells for fluid sample analysis, the fluidic layer comprising: (i) a sample inlet that receives a fluid sample; (ii) a plurality of wells; (iii) at least one channel that transports the fluid sample from the sample inlet to the wells; and (iv) an outlet coupled to the channel and a waste reservoir; and (c) bonding the inner surface of the patterned layer with an upper surface of the fluidic layer; (d) wherein the reagents of the pattern of reagents of the patterning layer are positioned within the plurality of wells of the fluidic layer; and (e) wherein the fluid sample flows automatically by degas driven flow.

11. The method of any preceding embodiment, the fluidic layer further comprising: a plurality of vacuum channels adjacent to the fluid channels and wells; a vacuum battery void comprising a volume configured to store a vacuum coupled to and in communication with the vacuum channels; wherein the stored vacuum within the vacuum battery void is configured to passively draw air across gas-permeable walls into the vacuum battery void to advance the fluid sample into the fluid channels and wells.

12. The method of any preceding embodiment, the fluidic layer further comprising: a plurality of interdigitating vacuum lines and fluid lines connected to the fluid channels, the fluid lines and the vacuum lines separated by gas permeable walls; and a vacuum battery void comprising a volume configured to store a vacuum coupled to and in communication with the vacuum lines; wherein the stored vacuum within the vacuum battery void is configured to passively draw air across gas permeable walls into the vacuum battery void to advance the fluid sample into the fluid channels and wells; and wherein flow properties of fluid in the plurality of fluid channels is regulated by the number of interdigitating vacuum lines and fluid lines.

13. The method of any preceding embodiment, the fluidic layer further comprising: a plurality of auxiliary vacuum channels adjacent to a plurality of wells separated gas-permeable walls; and an auxiliary vacuum battery void coupled to auxiliary vacuum channels; the auxiliary vacuum battery void comprising a volume configured to store a vacuum upon subjecting the chip to a vacuum state; wherein the stored vacuum within the auxiliary vacuum battery void draws air across the gas-permeable walls to advance the fluid sample into the plurality wells.

14. The method of any preceding embodiment, further comprising:

sealing an outer surface of the bonded pattern layer with a top sealing layer; and sealing a bottom surface of the bonded fluidic layer with a bottom sealing layer.

15. The method of any preceding embodiment, the fluidic layer further comprising: at least one cliff structure positioned in between the channel and each of the wells, the structure configured to skim the fluid sample and prevent particles in the fluid sample from entering the wells.

16. The method of any preceding embodiment, wherein the patterning an inner surface of a pattern layer of a gas permeable material with one or more reagents comprises: (a) forming a stencil with and inlet and a defined pattern of a plurality of fluidic channels and terminal cavities; (b) reversibly coupling the stencil with the inner surface of the pattern layer; (c) loading a fluid with a reagent to be patterned in the fluidic channels and cavities through the inlet; (d) clearing the channels of fluid; (e) removing the remaining liquid within the cavities to leave the reagent; and (f) separating the stencil from the pattern layer; (g) wherein the reagent is adhered to the pattern layer in a pattern defined by the cavities of the stencil.

17. The method of any preceding embodiment, further comprising: treating the inner surface of the pattern layer to be hydrophilic; and forming the stencil with surfaces that are hydrophobic; wherein materials are preferentially patterned onto the surface of the substrate by surface energy differences between the inner surface of the pattern layer and stencil.

18. The method of any preceding embodiment, wherein the surface energy difference on the surfaces of the pattern layer or stencil is created by a process selected from the group of process consisting of a plasma treatment, a UV ozone treatment, an application of a coating, and a heat treatment.

19. The method of any preceding embodiment, wherein the cavities of the stencil further comprise: an asymmetric apex shape; wherein removing the remaining liquid within the cavities concentrates the material in the apex; and wherein removing the remaining liquid within the cavities reduces the dimensions of material.

20. The method of any preceding embodiment, wherein the cavities of the stencil have an arcuate side wall and a linear sidewall joined at an apex to form the asymmetric shape of the cavity.

21. The method of any preceding embodiment, wherein the reagent is a reagent selected from the group or reagents consisting of MgOAc, DNA, RNA, an enzyme and a protein.

22. An apparatus for microfluidic sample analysis, the apparatus comprising: (a) a pattern layer of a gas permeable material that is patterned with one or more reagents; (b) a fluidic layer of a gas permeable material bonded to the pattern, the fluidic layer comprising: (i) a plurality of wells; (ii) a sample inlet that receives the fluid sample; (iii) at least one channel that transports the fluid sample from the sample inlet to one or more wells; (iv) at least one cliff structure positioned in between the channel and each well, configured to skim the fluid sample and prevent particles in the fluid sample from entering the wells, wherein the wells hold skimmed fluid sample for analysis; and (v) an outlet for fluid sample to flow out of the channel; (c) a top sealing layer configured to seal the pattern layer; and (d) a top sealing layer configured to seal the fluidic layer; (e) wherein the reagents are positioned within the wells.

23. The apparatus of any preceding embodiment, the fluidic layer further comprising: a plurality of interdigitating vacuum lines and fluid lines connected to the fluid channels, the fluid lines and the vacuum lines separated by gas permeable walls; and a vacuum battery void comprising a volume configured to store a vacuum coupled to and in communication with the vacuum lines; wherein the stored vacuum within the vacuum battery void is configured to passively draw air across gas permeable walls into the vacuum battery void to advance the fluid sample into the fluid channels and wells; and wherein flow properties of fluid in the plurality of fluid channels is regulated by the number of interdigitating vacuum lines and fluid lines.

24. The apparatus of any preceding embodiment, the fluidic layer further comprising: a plurality of auxiliary vacuum channels adjacent to a plurality of wells separated gas-permeable walls; and an auxiliary vacuum battery void coupled to auxiliary vacuum channels; the auxiliary vacuum battery void comprising a volume configured to store a vacuum upon subjecting the chip to a vacuum state; wherein the stored vacuum within the auxiliary vacuum battery void draws air across the gas-permeable walls to advance the fluid sample into the plurality wells.

25. An apparatus for microfluidic sample analysis, the apparatus comprising: (a) a pattern layer of a gas permeable material that is patterned with one or more reagents; (b) a fluidic layer of a gas permeable material bonded to the pattern, said fluidic layer comprising: (i) a plurality of wells; (ii) a sample inlet that receives the fluid sample; (iii) at least one channel that transports the fluid sample from the sample inlet to one or more wells; (iv) at least one cliff structure positioned in between the channel and each well, configured to skim the fluid sample and prevent particles in the fluid sample from entering the wells, wherein the wells hold skimmed fluid sample for analysis; (v) an outlet for fluid sample to flow out of the channel; (vi) a plurality of interdigitating vacuum lines and fluid lines connected to the fluid channels, said fluid lines and said vacuum lines separated by gas permeable walls; and (vii) a vacuum battery void comprising a volume configured to store a vacuum coupled to and in communication with the vacuum lines; (viii) wherein the stored vacuum within the vacuum battery void is configured to passively draw air across gas permeable walls into the vacuum battery void to advance the fluid sample into the fluid channels and wells; and (ix) wherein flow properties of fluid in the plurality of fluid channels is regulated by the number of interdigitating vacuum lines and fluid lines; (c) a top sealing layer configured to seal the pattern layer; and (d) a top sealing layer configured to seal the fluidic layer; (e) wherein the reagents are positioned within the wells.

26. An apparatus for microfluidic sample analysis, the apparatus comprising: (a) a pattern layer of a gas permeable material that is patterned with one or more reagents; (b) a fluidic layer of a gas permeable material bonded to the pattern, said fluidic layer comprising: (i) a plurality of wells; (ii) a sample inlet that receives the fluid sample; (iii) at least one channel that transports the fluid sample from the sample inlet to one or more wells; (iv) at least one cliff structure positioned in between the channel and each well, configured to skim the fluid sample and prevent particles in the fluid sample from entering the wells, wherein the wells hold skimmed fluid sample for analysis; (v) an outlet for fluid sample to flow out of the channel; (vi) a plurality of auxiliary vacuum channels adjacent to a plurality of wells separated gas-permeable walls; and (vii) an auxiliary vacuum battery void coupled to auxiliary vacuum channels; (viii) the auxiliary vacuum battery void comprising a volume configured to store a vacuum upon subjecting the chip to a vacuum state; (ix) wherein the stored vacuum within the auxiliary vacuum battery void draws air across the gas-permeable walls to advance the fluid sample into the plurality wells; (c) a top sealing layer configured to seal the pattern layer; and (d) a top sealing layer configured to seal the fluidic layer; (e) wherein the reagents are positioned within the wells.

27. The apparatus of any preceding embodiment, further comprising: a fluorescence detector for detection of components of the fluid sample; wherein said components are labeled with fluorescent labels; and wherein endpoint fluorescence data is collected by either a fluorescence microscope or smartphone equipped with filters.

Although the description herein contains many details, these should not be construed as limiting the scope of the disclosure but as merely providing illustrations of some of the presently preferred embodiments. Therefore, it will be appreciated that the scope of the disclosure fully encompasses other embodiments which may become obvious to those skilled in the art.

In the claims, reference to an element in the singular is not intended to mean “one and only one” unless explicitly so stated, but rather “one or more.” All structural, chemical, and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

What is claimed is:

1. A method for micropatterning materials on a substrate, the method comprising:
(a) obtaining a substrate to be patterned;
(b) forming a stencil with and inlet and a defined pattern of a plurality of fluidic channels and terminal cavities;
(c) reversibly coupling the stencil with the substrate;
(d) loading a fluid with a material to be patterned in the fluidic channels and cavities through the inlet;
(e) clearing the channels of fluid;
(f) removing the remaining liquid within the cavities to leave the material; and
(g) separating the stencil from the substrate;
(h) wherein the material is adhered to the substrate in a pattern defined by the cavities of the stencil.

2. The method of claim 1, further comprising:
selecting a substrate that has a surface to be patterned that is hydrophilic; and
forming the stencil with surfaces that are hydrophobic;
wherein materials are preferentially patterned onto the surface of the substrate by surface energy differences between the substrate and stencil.

3. The method of claim 2, wherein said surface energy difference on the surfaces of the substrate or stencil is created by a process selected from the group of process consisting of a plasma treatment, a UV ozone treatment, an application of a coating, and a heat treatment.

4. The method of claim 1, wherein the stencil is made from a gas permeable material.

5. The method of claim 4, wherein microfluidic vacuum degas flow is used to load fluid in the defined patterns of channels and cavities.

6. The method of claim 1, wherein the cavities of the stencil further comprise:
an asymmetric apex shape;
wherein removing the remaining liquid within the cavities concentrates the material in the apex; and
wherein removing the remaining liquid within the cavities reduces the dimensions of material.

7. The method of claim 6, wherein the cavities of the stencil have an arcuate side wall, a linear sidewall joined at an apex to for the asymmetric shape of the cavity.

8. The method of claim 1, said stencil further comprising:
a second defined pattern of a plurality of fluidic channels and terminal cavities; and
a second inlet coupled to the fluidic channels;
wherein a second fluid with a second material can be loaded to the channels and cavities through the second inlet to produce a defined pattern of a second material.

9. The method of claim 8, wherein said cavities of the second pattern in the stencil further comprise:
an asymmetric apex shape;
wherein removing the remaining liquid within the cavities concentrates the material in the apex; and
wherein removing the remaining liquid within the cavities reduces the dimensions of material.

10. A method for fabricating a microfluidic chip for analysis of a fluid sample, the method comprising:
(a) patterning a pattern layer with one or more reagents;
(b) forming a fluidic layer configured to separate a fluid sample into wells for fluid sample analysis, said fluidic layer comprising:
(i) a sample inlet that receives a fluid sample;
(ii) a plurality of wells; and
(iii) at least one channel that transports the fluid sample from the sample inlet to the wells; and
(c) bonding the pattern layer to the fluidic layer;
(d) wherein at least one of the pattern layer or the fluidic layer comprises a gas permeable material.
(d) wherein the reagents are positioned within the plurality of wells of the fluidic layer; and
(e) wherein the fluid sample flows automatically by degas driven flow.

11. The method of claim 10, said fluidic layer further comprising:
a plurality of vacuum channels adjacent to said fluid channels and wells; and
a vacuum battery void comprising a volume configured to store a vacuum coupled to and in communication with the vacuum channels;
wherein the stored vacuum within the vacuum battery void is configured to passively draw air across gas-permeable walls into the vacuum battery void to advance the fluid sample into the fluid channels and wells.

12. The method of claim 10, said fluidic layer further comprising:
a plurality of interdigitating vacuum lines and fluid lines connected to the fluid channels, said fluid lines and said vacuum lines separated by gas permeable walls; and
a vacuum battery void comprising a volume configured to store a vacuum coupled to and in communication with the vacuum lines;
wherein the stored vacuum within the vacuum battery void is configured to passively draw air across gas permeable walls into the vacuum battery void to advance the fluid sample into the fluid channels and wells; and
wherein flow properties of fluid in the plurality of fluid channels is regulated by the number of interdigitating vacuum lines and fluid lines.

13. The method of claim 12, said fluidic layer further comprising:
a plurality of auxiliary vacuum channels adjacent to a plurality of wells separated gas-permeable walls; and
an auxiliary vacuum battery void coupled to auxiliary vacuum channels;
the auxiliary vacuum battery void comprising a volume configured to store a vacuum upon subjecting the chip to a vacuum state;
wherein the stored vacuum within the auxiliary vacuum battery void draws air across the gas-permeable walls to advance the fluid sample into the plurality wells.

14. The method of claim 13, further comprising:
sealing an outer surface of the bonded pattern layer with a top sealing layer; or
sealing a bottom surface of the bonded fluidic layer with a bottom sealing layer.

15. The method of claim 10, said fluidic layer further comprising:
at least one cliff structure positioned in between the channel and each of the wells, the structure configured to skim the fluid sample and prevent particles in the fluid sample from entering the wells.

16. The method of claim 10, wherein said patterning an inner surface of a pattern layer of a gas permeable material with one or more reagents comprises:
(a) forming a stencil with and inlet and a defined pattern of a plurality of fluidic channels and terminal cavities;
(b) reversibly coupling the stencil with the inner surface of the pattern layer;
(c) loading a fluid with a reagent to be patterned in the fluidic channels and cavities through the inlet;
(d) clearing the channels of fluid;
(e) removing the remaining liquid within the cavities to leave the reagent; and
(f) separating the stencil from the pattern layer;
(g) wherein the reagent is adhered to the pattern layer in a pattern defined by the cavities of the stencil.

17. The method of claim 16, further comprising:
treating the inner surface of the pattern layer to be hydrophilic; and
forming the stencil with surfaces that are hydrophobic;
wherein materials are preferentially patterned onto the surface of the substrate by surface energy differences between the inner surface of the pattern layer and stencil.

18. The method of claim 17, wherein said surface energy difference on the surfaces of the pattern layer or stencil is created by a process selected from the group of process consisting of a plasma treatment, a UV ozone treatment, an application of a coating, and a heat treatment.

19. The method of claim 16, wherein the cavities of the stencil further comprise:
an asymmetric apex shape;
wherein removing the remaining liquid within the cavities concentrates the material in the apex; and
wherein removing the remaining liquid within the cavities reduces the dimensions of material.

20. The method of claim 19, wherein the cavities of the stencil have an arcuate side wall and a linear sidewall joined at an apex to form the asymmetric shape of the cavity.

21. The method of claim 10, wherein said reagent is a reagent selected from the group of reagents consisting of MgOAc, DNA, RNA, nucleic acid amplification reagents, immunoassay reagents, enzymes, proteins, and combinations thereof.

22. An apparatus for microfluidic sample analysis, the apparatus comprising:
(a) at least one layer that is patterned with one or more reagents;
(b) a fluidic layer, said fluidic layer comprising:
(i) a plurality of microwells;
(ii) a sample inlet configured to receive a fluid sample;
(iii) at least one fluid channel configured to transport the fluid sample from the sample inlet to one or more said microwells;
(iv) at least one cliff structure positioned between said at least one fluid channel and each said microwell configured to compartmentalize the fluid sample into said microwells for analysis;
(v) wherein compartmentalized reactions in the microwells allow for independent reactions; and
(vi) at least one microcliff gap forming a narrow channel between said at least one fluid channel and each said microwell configured to aid compartmentalization; and
(c) at least one layer of a gas permeable material;
(d) wherein reagents are positioned within the microwells;
(e) wherein one or multiple biochemical reactions can occur in the microwells; and
(f) wherein the apparatus drives fluid flow by vacuum stored in the apparatus, not by external pumps.

23. The apparatus of claim 22, said fluidic layer further comprising:
a plurality of interdigitating vacuum lines and fluid lines connected to the fluid channels, said fluid lines and said vacuum lines separated by gas permeable walls; and
a vacuum battery void comprising a volume configured to store a vacuum coupled to and in communication with the vacuum lines;
wherein the stored vacuum within the vacuum battery void is configured to passively draw air across gas permeable walls into the vacuum battery void to advance the fluid sample into the fluid channels and wells; and
wherein flow properties of fluid in the plurality of fluid channels is regulated by the number of interdigitating vacuum lines and fluid lines.

24. The apparatus of claim 22, said fluidic layer further comprising:
a plurality of auxiliary vacuum channels adjacent to a plurality of separated gas-permeable walls; and
an auxiliary vacuum battery void coupled to auxiliary vacuum channels;
the auxiliary vacuum battery void comprising a volume configured to store a vacuum upon subjecting the chip to a vacuum state;
wherein the stored vacuum within the auxiliary vacuum battery void draws air across the gas-permeable walls to advance the fluid sample into the plurality wells.

25. The apparatus of claim 22, further comprising:
a fluorescence detector for detection of components of the fluid sample;
wherein said components are labeled with fluorescent labels; and
wherein endpoint fluorescence data is collected by either a fluorescence optical imaging system or smartphone equipped with filters.

26. An apparatus for microfluidic sample analysis, the apparatus comprising:
(a) a pattern layer that is patterned with one or more reagents;
(b) a fluidic layer bonded to the pattern layer, said fluidic layer comprising:
(i) a plurality of wells;
(ii) a sample inlet that receives the fluid sample;
(iii) at least one channel that transports the fluid sample from the sample inlet to one or more wells;
(iv) at least one cliff structure positioned in between the channel and each well;
(v) an outlet for fluid sample to flow out of the channel;
(vi) a plurality of interdigitating vacuum lines and fluid lines connected to the fluid channels, said fluid lines and said vacuum lines separated by gas permeable walls; and
(vii) a vacuum battery void comprising a volume configured to store a vacuum coupled to and in communication with the vacuum lines;
(viii) wherein the stored vacuum within the vacuum battery void is configured to passively draw air across gas permeable walls into the vacuum battery void to advance the fluid sample into the fluid channels and wells; and
(ix) wherein flow properties of fluid in the plurality of fluid channels is regulated by the number of interdigitating vacuum lines and fluid lines;
(c) a sealing layer configured to seal at least one of the fluidic or pattern layers.
(d) wherein the reagents are positioned within the wells.

27. The apparatus of claim 26, further comprising:
a fluorescence detector for detection of components of the fluid sample;
wherein said components are labeled with fluorescent labels; and
wherein endpoint fluorescence data is collected by either a fluorescence optical imaging system or smartphone equipped with filters.

28. An apparatus for microfluidic sample analysis, the apparatus comprising:
(a) a pattern layer that is patterned with one or more reagents;
(b) a fluidic layer bonded to the pattern layer, said fluidic layer comprising:
(i) a plurality of wells;
(ii) a sample inlet that receives the fluid sample;
(iii) at least one channel that transports the fluid sample from the sample inlet to one or more wells;
(iv) at least one cliff structure positioned in between the channel and each well, configured to skim the fluid sample and prevent particles in the fluid sample from entering the wells, wherein the wells hold skimmed fluid sample for analysis;
(v) an outlet for fluid sample to flow out of the channel;
(vi) a plurality of auxiliary vacuum channels adjacent to a plurality of wells separated gas-permeable walls; and
(vii) an auxiliary vacuum battery void coupled to auxiliary vacuum channels;
(viii) the auxiliary vacuum battery void comprising a volume configured to store a vacuum upon subjecting the chip to a vacuum state;
(ix) wherein the stored vacuum within the auxiliary vacuum battery void draws air across the gas-permeable walls to advance the fluid sample into the plurality wells; and
(c) a sealing layer configured to seal at least one of the pattern or fluidic layers;
(d) wherein the reagents are positioned within the wells.

29. The apparatus of claim 28, further comprising:
a fluorescence detector for detection of components of the fluid sample;
wherein said components are labeled with fluorescent labels; and
wherein endpoint fluorescence data is collected by either a fluorescence optical imaging system or smartphone equipped with filters.
